(19) United States
(12) Patent Application Publication
(10) Pub. No.: US 2004/0173866 A1
(43) Pub. Date: Sep. 9, 2004

(54) Photodiode and image sensor

(76) Inventors: Yuichi Egawa, Yokohama (JP); Shuji IKeda, Koganei (JP)

Correspondence Address: ANTONELLI, TERRY, STOUT & KRAUS, LLP, 1300 NORTH SEVENTEENTH STREET, SUITE 1800, ARLINGTON, VA, 22209-9889, US

(21) Appl. No.: 10/743,879

(22) Filed: Dec. 24, 2003

(30) Foreign Application Priority Data
Dec. 25, 2002 (JP) P2002-374129

(51) Int. Cl. H01L 31/06

(52) U.S. Cl. 257/462

(57) ABSTRACT

The invention provides a technology capable of preventing an excessive leak current in a pn junction of a photodiode. The n-type region of a photodiode is separated from a device isolating part and a p-type region of relatively high concentration is formed in such a way as to be in contact with the n-type region to reduce the effect which an interface state between the semiconductor substrate and the device isolating part or a stress caused by the crystal mismatching of a silicon single crystal constructing the semiconductor substrate produces on a depletion layer produced in the boundary between the n-type region and the p-type region of the photodiode, thereby reducing the leak current in the pn junction of the photodiode.

### TECHNICAL FIELD OF THE INVENTION

The present invention relates to a photodiode and a technology for manufacturing the same and in particular, to a technology effectively applied to a photodiode provided in a CMOS image sensor.

### BACKGROUND OF THE INVENTION

At present, in place of an image pickup tube and a photoelectric multiplier, an image sensor (solid state imaging device) is used as an imaging device for converting an image into an electric signal. The image sensor is constructed of many photoelectric conversion devices such as photodiodes two-dimensionally arranged and sequentially scans signal charge obtained in each photoelectric conversion device to an output terminal by switching or transferring and reads the signal charge from the output terminal. Various types of image sensors such as MOS (Metal Oxide Semiconductor), CCD (Charge Coupled Device), CPD (Charge Priming Device), and CSD (Charge Sweep Device) have been developed as an image sensor. An image sensor of a CMOS (Complementary MOS) type has become mainstream in a field for requiring speedup.

There are several kinds of CMOS image sensors and in general, a pixel of a light receiving part is constructed of a combination of a photodiode and a field effect transistor (Metal Insulator Semiconductor Field Effect Transistor: hereinafter referred to as “MISFET”). Pixels are arranged in an array and connected to vertical shift registers and horizontal shift registers. Incident light on each pixel is photoelectrically converted by the photodiode and each pixel is sequentially scanned by the vertical shift register and the horizontal shift register, whereby signals of all pixels are read at the output terminal (for example, see Yasuo Takemura, “CCD Camera Technologies”, Dec. 15, 1997, Corona Publishing Co., Ltd., pp. 37-41, and Kevin Ng. “Technology Review of Charge-Coupled Device and CMOS Based Electric Imagers”, Nov. 21, 2001 (retrieved on Oct. 10, 2002), retrieved from the Internet: <URL: http://www.eecg.toronto.edu/˜kphang/papers/2001/ng_CCD.pdf>).

In this respect, the following construction is disclosed (for example, see Japanese Patent Application Laid-open No. 10-326341): in the pixel constructed of a light receiving region and a switching region, the light receiving region is arranged adjacently to the switching region and the light receiving region of each pixel is arranged adjacently to the light receiving region of the pixel adjacent thereto in a predetermined one-dimensional direction.

Further, a method is disclosed (for example, see Japanese Patent Application Laid-open No. 10-308507) in which the depth of an n-type region from the surface of a substrate of a photoelectric conversing part of a photodiode or the like is made larger than the depth of a device isolating insulating layer from the surface of the substrate of the photoelectric conversing part to prevent a reproduced image from being remarkably degraded by a leak current.

Still further, a method is disclosed (for example, see U.S. Pat. No. 6,215,165B1) in which in a photodiode having a trench isolating region, a buffer is formed between the trench isolating region and a diffusion constructing a pn junction to reduce a leak current.

One pixel of the light receiving part of the CMOS image sensor is constructed of, for example, an n⁺-p junction photodiode and an n-channel MISFET. The photodiode is constructed of an n⁺-type region where n-type impurities are introduced and a p-type region where p-type impurities are introduced. The n⁺-type region is formed by the same process as an n-type region constructing the source and drain of an n-channel MISFET and the p-type region is formed by the same process as a p-well. Further, photodiodes adjacent to each other are electrically isolated by a device isolating part.

By the way, in a case where an inverse bias is applied to the photodiode (in a case where a positive voltage higher than a voltage applied to the p-type region is applied to the n⁺-type region), a micro-current, a so-called leak current flows. When the leak current flows even if it is micro-current, there are presented problems that the noise level of an image is increased and that a standby current is increased to increase power consumption. For this reason, reducing the leak current is an important problem in the photodiode.

However, the inventors' study reveals that when the n⁺-type region of the photodiode is brought into direct contact with the device isolating part, the leak current is increased by the effect of an interface state or the crystal mismatching of a substrate. Then, the inventors' study reveals that even if the n⁺-type region of the photodiode is separated from the device isolating part, if the impurity concentration of the p-type region is not adequate, a depletion layer is widely expanded to increase the leak current.

An object of the invention is to provide a technology capable of preventing an excessive leak current in a pn junction of a photodiode.

The above-mentioned object and the other objects and new features of the present invention will be clearly understood by the description of the specification and the accompanying drawings.

### SUMMARY OF THE INVENTION

Of the inventions disclosed in this application, a typical invention will be described in brief as follows.

The invention forms a device isolating part in such a way as to be adjacent to the main surface of a semiconductor substrate made of a p-type silicon single crystal and constructs, in an active region surrounded by the device isolating part, a photodiode including a p-well of relatively low concentration, an n-type region separated from the device isolating part and surrounded by the p-well, and a p-type region that is in contact with the main surface of the semiconductor substrate and the n-type region and has a relatively high impurity concentration.

The invention forms a device isolating part in such a way as to be adjacent to the main surface of a semiconductor substrate made of a p-type silicon single crystal and constructs, in an active region surrounded by the device isolating part, a photodiode including a p-well of relatively low concentration, an n-type region separated from the device isolating part and surrounded by the p-well, and a p-type region that is in contact with the main surface of the semiconductor substrate and the n-type region and has a relatively high impurity concentration, and constructs an image sensor out of the photodiode and a field effect transistor including an n-type region that is connected on one side to the n-type region of the photodiode and constructs a source and a drain.

### BRIEF DESCRIPTIONS OF THE DRAWINGS

FIG. 1 is an equivalent circuit of one pixel constructing a light receiving part of an image sensor of the present embodiment 1;

FIG. 2 is a plan layout of one pixel constructing the light receiving part of the image sensor of the present embodiment 1;

FIG. 3 is a cross sectional view of a main portion of a semiconductor substrate along a line A-A′ in FIG. 2;

FIG. 4 is a graph showing the current-voltage characteristics of the pn junction of the photodiode of the present embodiment 1 and the current-voltage characteristics of the pn junction of the photodiode studied by the inventors;

FIG. 5 is a cross sectional view of a main portion of the semiconductor substrate to show one example of a method of manufacturing a pixel constructing the light receiving part of the image sensor of the present embodiment 1;

FIG. 6 is a cross sectional view of a main portion of the semiconductor substrate to show one example of a method of manufacturing a pixel constructing the light receiving part of the image sensor of the present embodiment 1;

FIG. 7 is a cross sectional view of a main portion of the semiconductor substrate to show one example of a method of manufacturing a pixel constructing the light receiving part of the image sensor of the present embodiment 1;

FIG. 8 is a cross sectional view of a main portion of the semiconductor substrate to show one example of a method of manufacturing a pixel constructing the light receiving part of the image sensor of the present embodiment 1;

FIG. 9 is a cross sectional view of a main portion of the semiconductor substrate to show one example of a method of manufacturing a pixel constructing the light receiving part of the image sensor of the present embodiment 1;

FIG. 10 is a cross sectional view of a main portion of the semiconductor substrate to show one example of a method of manufacturing a pixel constructing the light receiving part of the image sensor of the present embodiment 1;

FIG. 11 is a plan layout of one pixel constructing the light receiving part of an image sensor of the present embodiment 2;

FIG. 12 is a cross sectional view of a main portion of a semiconductor substrate along a line B-B′ in FIG. 11;

FIG. 13 is a cross sectional view of a main portion of a semiconductor substrate to show one pixel constructing the light receiving part of an image sensor of the present embodiment 3; and

FIG. 14 is a cross sectional view of a main portion of a semiconductor substrate to show one pixel constructing the light receiving part of an image sensor of the present embodiment 4.

### DESCRIPTION OF THE PREFERRED EMBODIMENTS

The preferred embodiments of the invention will be hereinafter described in detail on the basis of drawings. Here, through the drawings for describing the preferred embodiments, parts having the same function will be designated by the same reference symbols and their repeated descriptions will be omitted.

### Embodiment 1

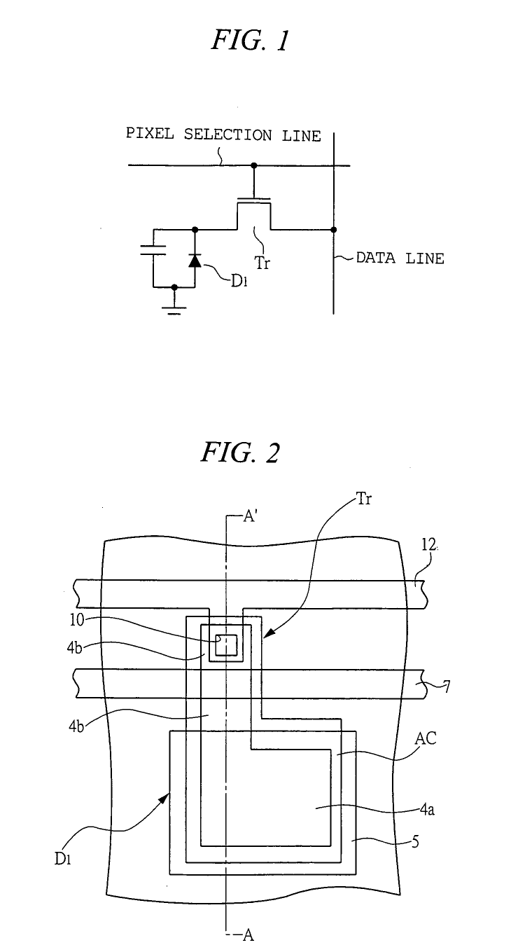

FIG. 1 is an equivalent circuit of one pixel constructing a light receiving part of an image sensor of the present embodiment 1.

Each pixel constructing the light receiving part of the image sensor has a photodiode D₁ and a MISFET Tr functioning as a switch at the time of transmitting a signal charge stored in the photodiode D₁ to the outside of the pixel. Each pixel is switched via a pixel selection line by a pulse applied to the gate of the MISFET Tr, whereby the signal charge stored in the photodiode D₁ is taken out via a data line to an output. When incident light on each pixel is photoelectrically converted by the photodiode D₁, whereby the signal charge responsive to the intensity of the light is stored in the course of time.

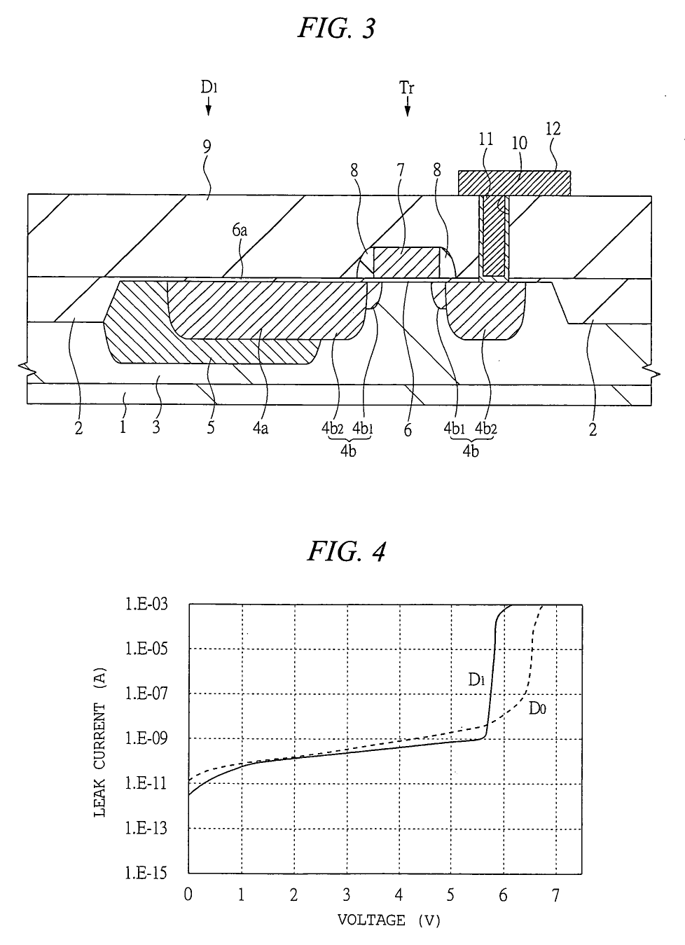

FIG. 2 is a plan layout of one pixel constructing the light receiving part of the image sensor of the present embodiment 1. FIG. 3 is a cross sectional view of a main portion of a semiconductor substrate along a line A-A′ in FIG. 2.

An active region AC surrounded by a device isolating part 2 is formed in the main surface of a semiconductor substrate 1 made of a p-type silicon polycrystal film. In the active region AC is formed a p-well 3 of relatively low concentration into which p-type impurities, for example, boron are introduced. Then, an n-type region 4a of the photodiode D₁ into which n-type impurities, for example, phosphorous or arsenic are introduced is formed in the main surface of the semiconductor substrate 1. Then, the pn junction of the photodiode D₁ is constructed between the p-well 3 and the n-type region 4a.

Further, a pair of n-type regions 4b constructing the source and the drain of a MISFET Tr into which n-type impurities are introduced are formed in the main surface of the semiconductor substrate 1. The n-type regions 4b are constructed of an n-type extension region 4b₁ of relatively low concentration and an n-type extension region 4b₂ of relatively high concentration. The n-type region 4a of the photodiode D₁ is joined to and electrically connected to the n-type region 4b constructing one of the source and the drain of the MISFET Tr. The impurity concentrations of the n-type region 4a and the n-type extension region 4b₂ range, for example, from about 10²⁰ cm⁻³ to 10²² cm⁻³. Here, a part of the n-type region 4a of the photodiode D₁ may also serve as the n-type extension region 4b₂ constructing one of the source and the drain of the MISFET Tr.

A p-type region 5 into which p-type impurities, for example, boron are introduced is extended along a surface opposite to the main surface of the semiconductor substrate 1 of the n-type region 4a of the photodiode D₁ (a surface at which the n-type region 4a is in contact with the p-well 3 and which is parallel to the main surface of the semiconductor substrate 1) and the n-type region 4a is substantially surrounded by the p-type region 5. The impurity concentration of the p-type region 5 is relatively high as compared with the impurity concentration of the p-well 3 and ranges, for example, from about 10¹⁷ cm⁻³ to 10¹⁹ cm⁻³. The p-type region 5 is formed at a location at least a distance of extension length of the p-type region 5 away from the gate electrode 7 of the MISFET Tr and the distance between the gate electrode 7 and the p-type region 5 ranges, for example, from about 1 μm to 2 μm.

Then, in order to prevent a depletion layer produced in a boundary between the n-type region 4a and the p-type region 5 of the photodiode D₁ from being affected by a stress caused by an interface state produced near the interface between the semiconductor substrate 1 and the device isolating part 2 or the crystal mismatching of a silicon single crystal constructing the semiconductor substrate 1, the n-type region 4a is formed at a location, for example, about 0.5 μm to 2.0 μm away from the device isolating part 2. Moreover, the p-type region 5 is formed between the n-type region 4a and the device isolating part 2 in such a way as to be in contact with the device isolating part 2.

A threshold voltage control layer, although not shown, is formed between the pair of n-type regions 4b constructing the source and the drain of the MISFET Tr. A gate insulation film 6 made of a silicon oxide film 6a is formed over the threshold voltage control layer. The silicon oxide film 6a is formed by a thermal oxidation method or a CVD method and is formed also over the surface of the semiconductor substrate 1 except for the region where the MISFET Tr is formed. Then, the gate electrode 7 made of a silicon polycrystal film is formed over the gate insulation film 6. The gate electrode 7 functions also as a pixel selection line. Here, the gate electrode 7 can be constructed of a laminated film in which the silicon polycrystal film and a silicide film are deposited sequentially from a lower layer or a laminated film in which the silicon polycrystal film and a metal film are deposited sequentially from a lower layer.

Side wall spacers 8 are formed on the side walls of the gate electrode 7 of the MISFET Tr and an insulation film 9 made of a silicon oxide film, for example, is formed as the upper layer of the gate electrode 7. A contact hole 10 reaching the other n-type region 4b not joined to the n-type region 4a of the photodiode D₁ is made in the insulation film 9. A barrier film, for example, a titan nitride film and a metal film, for example, a tungsten film are buried in the contact hole 10 to form a plug 11. Then, a wiring (data line) 12 is connected via the plug 10 to the other n-type region 4b which is not connected to the n-type region 4a of the photodiode D₁.

FIG. 4 is a graph showing the current-voltage characteristics of the pn junction of the photodiode of the present embodiment 1 and the current-voltage characteristics of the pn junction of the photodiode studied by the inventors. The photodiode studied by the inventors has a pn junction structure including a p-well and an n-type region in contact with a device isolating part.

It is clear that when voltage is 0 V, the leak current of the photodiode D₁ of the present embodiment 1 is reduced to about ½ as compared with the leak current of the photodiode D0 studied by the inventors.

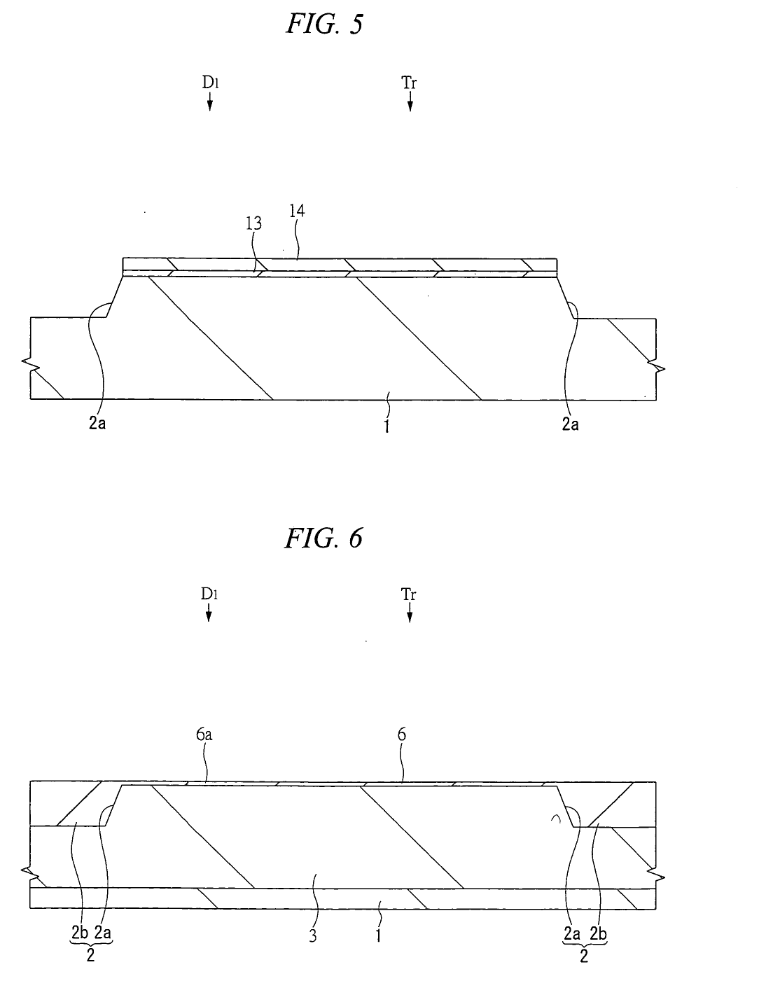

Next, one example of a method of manufacturing a pixel constructing the light receiving part of an image sensor of the present embodiment 1 will be shown in the order of steps by the use of cross sectional views of a main portion of a semiconductor substrate shown in FIG. 5 to FIG. 10.

First, as shown in FIG. 5, the semiconductor substrate 1 made of, for example, a p-type silicon single crystal (semiconductor wafer worked into a circular thin plate) is prepared. Next, the semiconductor substrate 1 is thermally oxidized to form a silicon oxide film 13 having a thickness of about 0.01 μm on its surface. Then, a silicon nitride film 14 of about 0.1 μm in thickness is deposited over the silicon oxide film 13 by a CVD (Chemical Vapor Deposition) method. Then, the silicon nitride film 14, the silicon oxide film 13 and the semiconductor substrate 1 are etched in sequence by using a resist pattern as a mask to form a device isolating trench 2a of about 0.35 μm in depth in the semiconductor substrate 1 in the device isolating region.

Next, as shown in FIG. 6, a silicon oxide film 2b is deposited over the semiconductor substrate 1 and then the semiconductor substrate 1 is annealed at about 1000° C. to thermally densificate the silicon oxide film 2b. Then, the silicon oxide film 2b is etched by an etch back method or is polished by a CMP (Chemical Mechanical Polishing) method to form the device isolating part 2 by leaving the silicon oxide film 2b in the device isolating trench 2a. Thereafter, the silicon nitride film 14 is removed by a wet etching method using hot phosphoric acid.

In this respect, it is also available to provide a step of forming a silicon oxide film by the thermal oxidation method before depositing the silicon oxide film 2b over the semiconductor substrate 1 and then of wet etching the silicon oxide film by a water solution of hydrofluoric acid. This step can further clean the interface between the semiconductor substrate 1 and the silicon oxide film 2b. Then, a LOCOS (Local Oxidation of Silicon) method may be used for forming the device isolating part 2.

Next, impurities are ion implanted into the semiconductor substrate 1 to form the p-well 3. For the p-well 3, impurities showing a p-type conduction type, for example, boron are ion implanted. For example, conditions for ion implanting boron as p-type impurities are as follows: energy=100 keV, amount of dose=5×10¹² cm⁻²; and energy=15 keV, amount of dose=5×10¹² cm⁻². Thereafter, impurities for controlling the threshold of the MISFET Tr may be ion implanted into the p-well 3. Then, the silicon oxide film 6a which becomes the gate insulation film 6 in the region where the MISFET Tr is formed is formed on the surface of the semiconductor substrate 1 by the thermal oxidation method or the CVD method.

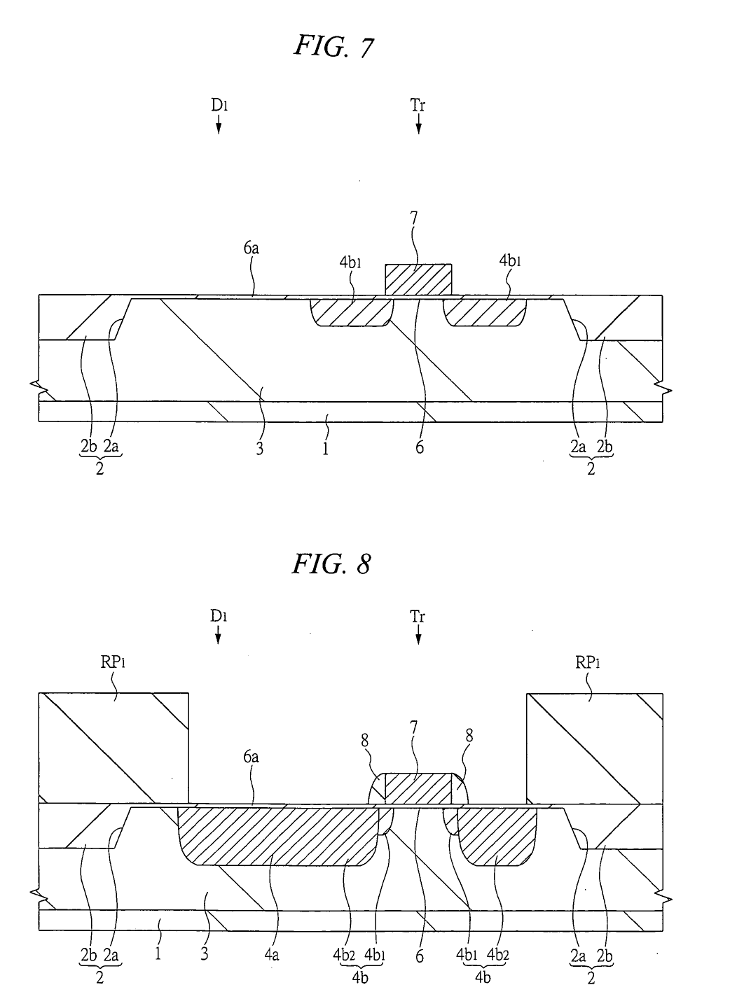

Next, as shown in FIG. 7, a silicon polycrystal film of about 200 nm in thickness into which n-type impurities, for example, phosphorous are introduced is deposited over the semiconductor substrate 1 by the CVD method and then the silicon polycrystal film is etched by using a resist pattern as a mask to form the gate electrode 7 made of the silicon polycrystal film. Thereafter, the semiconductor substrate 1 is subjected to a dry oxidation processing at about 800° C., for example.

Next, n-type impurities, for example, phosphorus or arsenic are ion implanted into the semiconductor substrate 1 to form the n-type extension region 4b₁ constructing the source and the drain. For example, conditions for ion implanting phosphorus as n-type impurities are as follows: energy=60 keV, amount of dose=10¹³ cm⁻².

Next, as shown in FIG. 8, a silicon oxide film of about 150 nm in thickness is deposited over the semiconductor substrate 1 and then the silicon oxide film is anisotropically etched, for example, by a RIE (Reactive Ion Etching) method to form the side wall spacers 8 on the side walls of the gate electrode 7.

Next, n-type impurities, for example, phosphorous or arsenic are ion implanted into the semiconductor substrate 1 by using a resist pattern RP₁ as a mask to form the n-type region 4a of the photodiode D₁ and the n-type extension region 4b₂ constructing the source and the drain of the MISFET Tr. In the resist pattern RP₁, a hole for an active region is formed at a location about 0.5 μm to 2 μm away from the device isolating part 2. For example, conditions for ion implanting arsenic as n-type impurities are as follows: energy=80 keV, amount of dose=10¹⁵ cm⁻². Thereby, the n-type extension region 4b constructing the source and the drain by the n-type extension region 4b₁ and the n-type extension region 4b₂ is formed in the MISFET Tr. In this case, by making the impurity concentration of the n-type extension region 4b₁ relatively low and by making the impurity concentration of the n-type extension region 4b₂ relatively high, there are formed the source and the drain that have an LDD (Lightly Doped Drain) structure capable of relaxing an electric field at the end of the gate electrode 7.

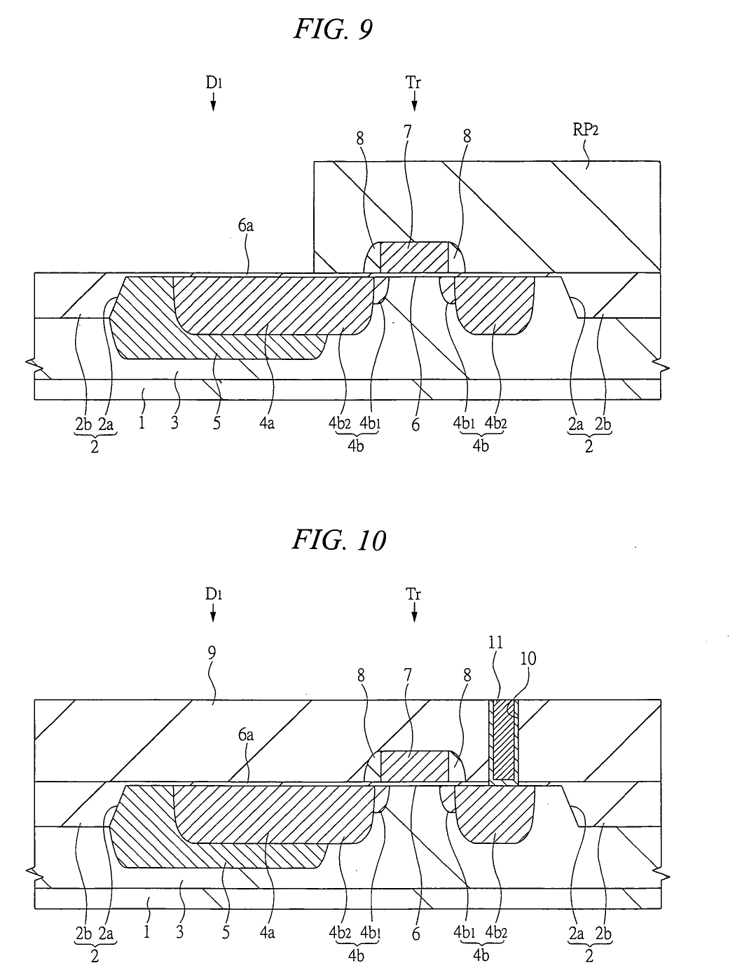

Next, as shown in FIG. 9, the resister pattern RP₁ is removed and then the semiconductor substrate 1 is annealed, for example, at 1000° C. for 10 seconds. Then, p-type impurities, for example, boron are ion implanted into the semiconductor substrate 1 by using a resist pattern RP₂ as a mask to form the p-type region 5. In the resist pattern RP₂ is formed a hole for the n-type region 4a where the photodiode D₁ is formed and p-type impurities are ion implanted in a tilting direction into the semiconductor substrate 1. For example, conditions for ion implanting boron as p-type impurities are as follows: tilt angle=45°, energy=100 keV and amount of dose=10¹³ cm⁻². Since the p-type region 5 is formed only in the n-type region 4a where the photodiode D₁ is formed, the optimum concentration of the p-type region 5 can be set without considering various characteristics of the MISFET Tr.

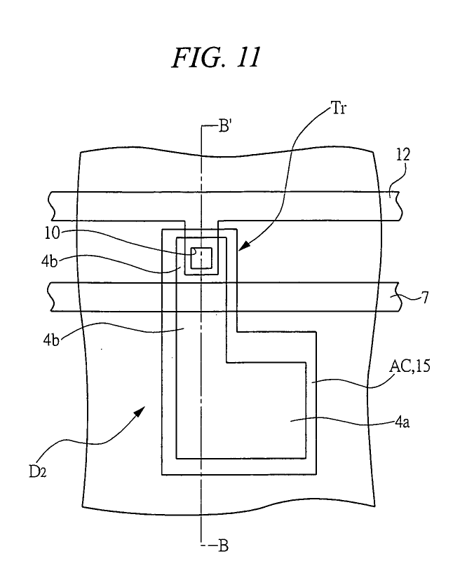

Next, as shown in FIG. 10, the insulation film 9 made of, for example, the silicon oxide film is formed on the semiconductor substrate 1 and the insulation film 9 is polished by the CMP method to planarize the surface thereof. Next, the insulation film 9 is etched by using a resist pattern as a mask to form a contact hole 10 in the insulation film 9. The contact hole 10 is formed in a necessary portion such as above the other n-type region 4b constructing the source and the drain of the MISFET Tr.

Further, a laminated film of a titan film and a titan nitride film is formed over the whole surface of the semiconductor substrate 1 including the inside of the contact hole 10, for example, by the CVD method and then a tungsten film buried in the contact hole 10 is formed, for example, by the CVD method. Thereafter, the titan nitride film and the tungsten film in the region except for the contact hole 10 are removed, for example, by the CMP method to form the plug 11 in the contact hole 10.

Next, for example, an aluminum alloy film is formed over the semiconductor substrate 1 and then the aluminum alloy film is etched by using a resist pattern as a mask to form the wiring 12 as shown in FIG. 3. The aluminum alloy film can be formed, for example, by a sputtering method. Thereafter, the whole surface of the semiconductor substrate 1 is covered with a passivation film to nearly complete the light receiving part of the image sensor made of the photodiode D₁, and the MISFET Tr.

In this respect, while the insulation film formed over the surface of the semiconductor substrate 1 is formed of the silicon oxide film 6a which is the same layer as the gate insulation film 6 in the present embodiment 1, it is not intended to limit the insulation film to this silicon oxide film 6a. For example, in a step after forming the side wall spacers, the surface of the semiconductor substrate 1 is exposed by a cleaning processing and then a silicon oxide film is formed by the thermal oxidation method or the CVD method.

As described above, according to the present embodiment 1, by separating the n-type region 4a of the photodiode D₁ from the device isolating part 2 and by forming the p-type region 5 which substantially surrounds the n-type region 4a and has a relatively high concentration, the depletion layer produced in the boundary between the n-type region 4a and the p-type region 5 of the photodiode D₁ becomes resistant to being affected by the stress caused by the interface state produced near the interface between the semiconductor substrate 1 and the device isolating part 2 or caused by the crystal mismatching of the silicon single crystal constructing the semiconductor substrate 1, so that the leak current in the pn junction of the photodiode D₁ can be reduced. Further, since the n-type region 4a is formed only in the region where the photodiode D₁, is formed, the optimum concentration of the p-type region 5 can be set without considering various characteristics of the MISFET Tr.

### Embodiment 2

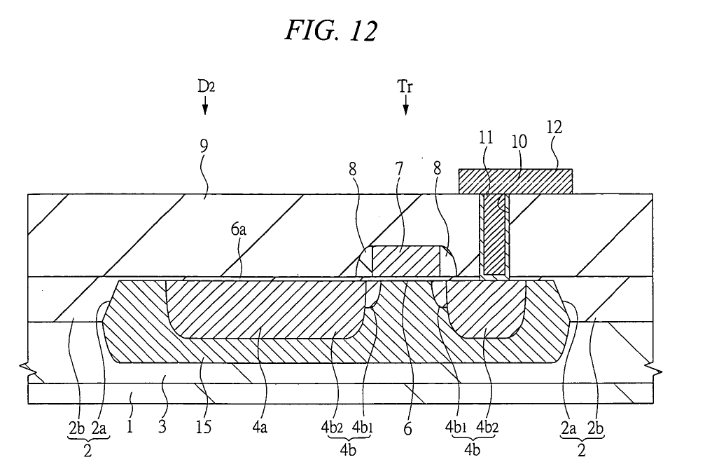

FIG. 11 is a plan layout of one pixel constructing the light receiving part of the image sensor of the present embodiment 2. FIG. 12 is a cross sectional view of a main portion of a semiconductor substrate along a line B-B′ in FIG. 11.

As is the case with the pixel constructing the light receiving part of the image sensor shown in the embodiment 1 mentioned above, a photodiode D₂ of a pn junction including the p-type well 3 and the n-type region 4a and the MISFET Tr including the source and the drain (n-type region 4b), the gate insulation film 6 and the gate electrode 7 are formed over the main surface of the semiconductor substrate 1. The n-type regions 4a, 4b are formed at locations for example, about 0.5 μm to 2.0 μm away from the device isolating part 2.

In the present embodiment 2, the p-type region 15 is formed between the n-type regions 4a, 4b and the device isolating part 2 and further the n-type region 4a of the photodiode D₂ and the n-type region 4b connected to this and constructing the source and the drain of the MISFET Tr are thoroughly surrounded by a p-type region 15. The p-type region 15 is formed in such a way as to wrap the n-type regions 4a, 4b by tilted ion implanting of the p-type impurities into the active region AC. For example, conditions for ion implanting boron as p-type impurities are as follows: tilt angle=45°, energy=100 keV and amount of dose=10¹³ cm⁻².

As described above, according to the present embodiment 2, by thoroughly surrounding the n-type region 4a of the photodiode D₂ and the n-type region 4b joined to this and constructing the source and the drain of the MISFET Tr by the p-type region 15, the leak current in the pn junction of the photodiode D₂ can be reduced.

### Embodiment 3

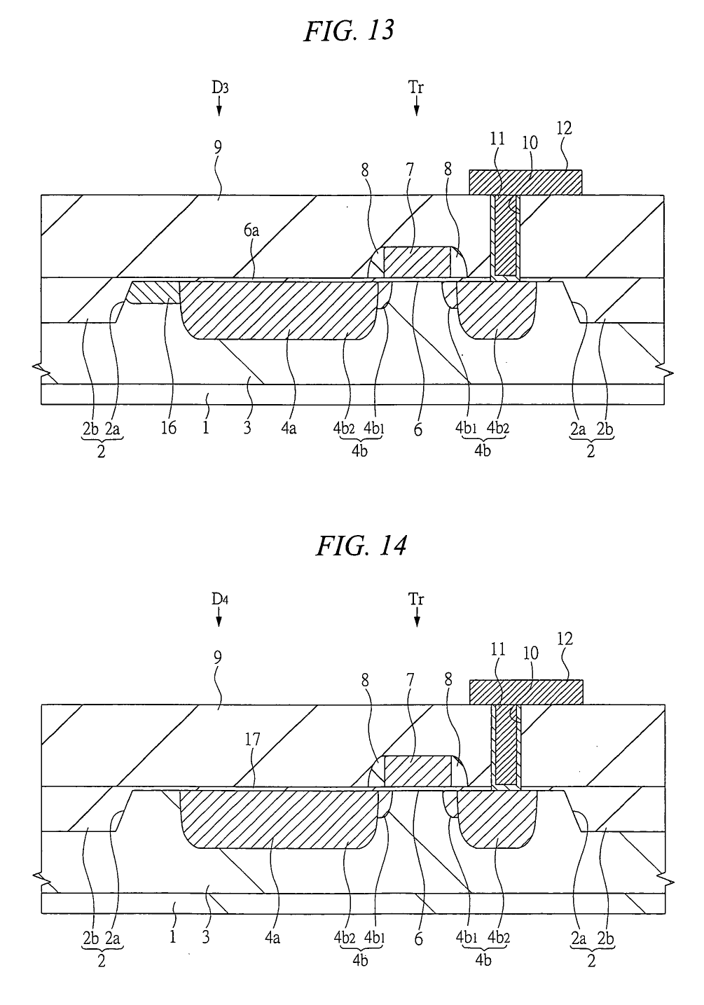

FIG. 13 is a cross sectional view of a main portion of a semiconductor substrate showing one pixel constructing the light receiving part of an image sensor of the present embodiment 3.

As is the case with the pixel constructing the light receiving part of the image sensor shown in the embodiment 1, a photodiode D₃ of the pn junction including the p-type well 3 and the n-type region 4a and the MISFET Tr including the source and the drain (n-type region 4b), the gate insulation film 6 and the gate electrode 7 are formed in the main surface of the semiconductor substrate 1. The n-type regions 4a, 4b are formed at locations for example, about 0.5 μm to 2.0 μm away from the device isolating part 2.

In the present embodiment 3, a p-type region 16 of relatively high concentration is formed in such a way to surround the side surface of the n-type region 4a close to the surface of the semiconductor substrate 1 of the photodiode D₃ and the p-type region 16 is formed between the side surface of the n-type region 4a close to the surface of the semiconductor substrate 1 and the device isolating part 2. The p-type region 16 is formed by ion implanting the p-type impurities in a tilting direction at relatively low energy by the use of a resist pattern having a hole made in the n-type region 4a where the photodiode D₃ is formed.

In this manner, according to the present embodiment 3, by forming the p-type region 16 in such a way as to surround the side surface of the n-type region 4a close to the surface of the semiconductor substrate 1 of the photodiode D₃, the leak current in the pn junction of the photodiode D₃ can be reduced. Further, when the p-type impurities for forming the p-type region 16 are ion implanted, energy can be reduced, so that damage caused to the semiconductor substrate 1 can be reduced.

### Embodiment 4

FIG. 14 is a cross sectional view of a main portion of a semiconductor substrate showing one pixel constructing the light receiving part of an image sensor of the present embodiment 4.

As is the case with the pixel constructing the light receiving part of the image sensor shown in the embodiment 1, a photodiode D₄ of the pn junction including the p-type well 3 and the n-type region 4a and the MISFET Tr including the source and the drain (n-type region 4b), the gate insulation film 6 and the gate electrode 7 are formed on the main surface of the semiconductor substrate 1. The n-type regions 4a, 4b are formed at locations for example, about 0.5 μn to 2.0 μm away from the device isolating part 2.

An insulation film formed over the surface of the semiconductor substrate 1 in the region where the photodiode D₄ is formed is formed of an insulation film formed by thermally oxidizing the semiconductor substrate 1, for example, a silicon oxide film 17. Then, the interface between the n-type region 4a and the well 3 of the photodiode D₄ in the surface of the semiconductor substrate 1 is covered with the silicon oxide film 17. The silicon oxide film 17 may be constructed of the silicon oxide film of the same layer as the gate insulation film 6 of the MISFET Tr. Alternatively, it is also available to form the side wall spacers 8 on the side walls of the gate electrode 7 of the MISFET Tr and then to clean the surface of the semiconductor substrate 1 by a water solution of hydrofluoric acid and then to construct, the silicon oxide film 17 out of a silicon oxide film formed by the thermal oxidation method.

In the present embodiment 4, the p-type region surrounding the n-type region 4a of the photodiode D₄ is not formed, but for example, a p-type region similar to the p-type regions 5, 15, 16 shown in the embodiments 1 to 3 may be formed. In this manner, the leak current can be reduced as compared with a case where the p-type region is not formed.

In this manner, according to the present embodiment 4, by covering the interface between the n-type region 4a and the p-well 3 of the photodiode D₄ in the surface of the semiconductor substrate 1 with the silicon oxide film 17 formed by the thermal oxidation method, the leak current of the pn junction of the photodiode D₄ can be reduced as compared with a case where the above-mentioned interface is covered with an insulation film formed by the CVD method, for example, a silicon oxide film or a silicon nitride film.

While the invention achieved by the inventors has been concretely described up to this point on the basis of the preferred embodiments, it is not intended to limit the invention to these preferred embodiments but needless to say, the invention may be further variously modified within the spirit and scope of the invention.

For example, while the cases where the invention is applied to the CMOS image sensor have been described in the embodiments, the invention can be also applied to the pixel of the other imaging devices such as CCD.

Further, in the above embodiments has been described a structure in which the n-type region is surrounded by the p-type region of relatively high concentration in the pn junction constructed of the n-type region and the p-well. However, even a structure in which the p-type region is surrounded by the n-type region of relatively high concentration in the pn junction constructed of the p-type region and the n-well can produce the same effect.

Advantages provided by a typical invention of the inventions disclosed in the present application will be described in brief as follows.

In the photodiode including the n-type region and the p-well, the n-type region is separated from the device isolating part and the p-type region of relatively high concentration is formed in such a way as to surround at least the n-type region close to the surface of the semiconductor substrate. In this manner, it is possible to make the depletion layer produced in the boundary between the n-type region and the p-type region of the photodiode resist being affected by the interface state or the stress and to reduce the leak current in the pn junction of the photodiode.

What is claimed is:

1. A photodiode, comprising in an active region surrounded by a device isolating part formed adjacent to a main surface of a semiconductor substrate:
a first region which is extended inward from said main surface and is of a first conduction type;
a second region which is separated from said device isolating part and is extended from said main surface into said first region and which is of a second conduction type different from the first conduction type; and
a third region which is extended into said first region in such a way to be in contact with said main surface and said second region and which is of the first conduction type having an impurity concentration higher than said first region.

2. The photodiode as claimed in claim 1, wherein said third region substantially surrounds said second region.

3. The photodiode as claimed in claim 1, wherein an interface between said second region and said third region in said semiconductor substrate is covered with an insulation film formed by a thermal oxidation method.

4. The photodiode as claimed in claim 1, wherein a distance between said second region and said device isolating part is larger than a width of a depletion layer which is spreading from an interface between said second region and said third region toward said device isolating part.

5. The photodiode as claimed in claim 1, wherein said third region is extended along a surface opposite to said main surface of said second region.

6. The photodiode as claimed in claim 1, wherein said third region is in contact with said device isolating part.

7. An image sensor having a pixel of a light receiving part, said pixel comprising:
a photodiode including in an active region surrounded by a device isolating part formed adjacent to a main surface of a semiconductor substrate: a first region which is extended inward from said main surface and is of a first conduction type; a second region which is separated from said device isolating part and is extended from said main surface into said first region and which is of a second conduction type different from the first conduction type; and a third region which is extended into said first region in such a way to be in contact with said main surface and said second region and which is of the first conduction type having an impurity concentration higher than said first region; and
a field effect transistor having a fourth region which is formed in said active region and constructs a source and a drain, one of which is joined to said second region of said photodiode, and which is of the second conduction type.

8. The image sensor as claimed in claim 7, wherein a part of said second region also serves as said fourth region.

9. The image sensor as claimed in claim 7, wherein said third region substantially surrounds said second region.

10. The image sensor as claimed in claim 7, wherein said third region is arranged at a location away from a gate electrode of said field effect transistor with at least a distance of diffusion length of said third region.

11. The image sensor as claimed in claim 7, wherein said third region substantially surrounds said second region and said fourth region.

12. The image sensor as claimed in claim 7, wherein an interface between said second region and said third region in said semiconductor substrate is covered with an insulation film formed by a thermal oxidation method.

13. The image sensor as claimed in claim 12, wherein said insulation film is the same layer as a gate insulation film of said field effect transistor.

14. The photodiode as claimed in claim 7, wherein a distance between said second region and said device isolating part is larger than a width of a depletion layer which is spreading from an interface between said second region and said third region to said device isolating part.

15. The photodiode as claimed in claim 7, wherein said third region is extended along a surface opposite to said main surface of said second region.

16. The photodiode as claimed in claim 7, wherein said second region and said fourth region are formed by the same process.

17. A photodiode, comprising in an active region surrounded by a device isolating part formed adjacent to a main surface of a semiconductor substrate:
a first region which is exposed to said main surface and is of a first conduction type;
a second region which is separated from said device isolating part and is exposed to said main surface and which is formed in said first region and has an impurity concentration higher than said first region; and
a third region which is located at a position where said device isolating part is close to said second region, which is in contact with said main surface, said device isolating part, said first region and said second region and which is of the first conduction type having an impurity concentration higher than said first region.

18. An image sensor having a pixel of a light receiving part, said pixel comprising:
a photodiode including in an active region surrounded by a device isolating part formed adjacent to a main surface of a semiconductor substrate: a first region which is exposed to said main surface and is of a first conduction type; a second region which is separated from said device isolating part and is exposed to said main surface and which is formed in said first region and has an impurity concentration higher than said first region; and a third region which is located at a position where said device isolating part is close to said second region, which is in contact with said main surface, said device isolating part, said first region and said second region and which is of the first conduction type having an impurity concentration higher than said first region; and
a field effect transistor having a fourth region which is formed in said active region and constructs a source and a drain, one of which is joined to said second region of said photodiode, and which is of the second conduction type.
